(19) United States
(12) Patent Application Publication
(10) Pub. No.: US 2012/0286308 A1
(43) Pub. Date: Nov. 15, 2012

(54) LED PACKAGE STRUCTURE AND METHOD OF FABRICATING THE SAME

(75) Inventors: Chieh-Lung Lai, Taichung (TW); Wen-Lin Chang, Taichung Hsien (TW); Chih-Sheng Hsu, Taichung Hsien (TW); Chang-Yueh Chan, Taichung Hsien (TW)

(73) Assignee: SILICONWARE PRECISION INDUSTRIES CO., LTD., Tantzu Hsien (TW)

(21) Appl. No.: 13/242,452

(22) Filed: Sep. 23, 2011

(30) Foreign Application Priority Data
May 11, 2011 (TW) 100116429

(51) Int. Cl. H01L 33/50; H01L 33/52; H01L 33/62

(52) U.S. Cl. 257/98; 257/99; 438/26; 257/E33.061; 257/E33.066; 257/E33.059

(57) ABSTRACT

An LED package structure and a method of fabricating the same. The LED package structure includes: a package unit including a submount with a cavity, and a light emitting chip disposed in the cavity; a first light-pervious element disposed in the cavity; a multi-layered dam structure concentrically disposed on the first light-pervious element or around a rim of the cavity; a first light-pervious packaging material filled in the dam structure; and a second light-pervious element that combines with the dam structure. Accordingly, the multi-layered dam structure provides an advantage of eliminating gaps and overcomes the problem resulting from the uneven thickness of the first light-pervious packaging material used in the prior technique, thereby ensuring high illumination efficiency and enhanced airtightness.

### BACKGROUND OF THE INVENTION

1. Field of the Invention

This invention relates to package structures and methods of fabricating the same, and, more particularly, to an LED package structure and a method of fabricating the same.

2. Description of Related Art

Silicon material has been applied in the modern package of light emitting diode (LED) for phosphor protection, and the silicon material has advantageous features of high light-pervious efficiency and high heat-resistance, thereby being frequently used for covering phosphor to isolate heat generated by the LED, but incapable of efficiently isolating vapor, consequently the phosphor will lose efficacy due to contacting with the vapor.

Please refer to FIG. 1, which is a sectional view diagram of an LED package structure according to US Patent Application Publication No. 2010/0163898. A substrate 11 with a circuit pattern 110 thereon is covered with a reflection layer 12, and a portion of the circuit pattern 110 is exposed therefrom. A light emitting chip 13 is mounted on the reflection layer 12, and is electrically connected to the exposed circuit pattern 110 via conductive element 14, e.g. conductive wire. A reflector 15 with a light reflecting opening 150 is disposed on the reflection layer 12, and the light emitting chip 13 is disposed in the light reflecting opening 150. The light reflecting opening 150 is filled with a packaging material 16 and phosphor layer 17. In order to enhance airtightness, a single ring of sealing glue (not shown) is coated on the rim of the light reflecting opening 150 of the reflector 15, and then the reflector 15 is covered with an optical microstructure film 18 to seal the light reflecting opening 150. However, both the packaging material 16 and the phosphor layer 17 are in a liquid form, and, in order to ensure the optical microstructure film 18 to seal up the light reflecting opening 150 of the reflector 15 tightly for preventing the packaging material 16 and the phosphor layer 17 from being spilt out, the phosphor layer 17 does not fill up the light reflecting opening 150, thereby causing a gap 19 to appear between the optical microstructure film 18 and the phosphor layer 17 after the optical microstructure film 18 sealing up the light reflecting opening 150, and further causing the thickness of the packaging material 16 or the phosphor layer 17 to become uneven, consequently the light emitting chip 13 cannot maintain high illumination efficiency and quality.

Hence, how to solve the problem occurred in the prior technique is a highly urgent technique issue in the industry.

### SUMMARY OF THE INVENTION

In view of the drawbacks of the prior art mentioned above, it is therefore an objective of this invention to provide an LED package structure, comprising: a package unit having a submount with a cavity, and a light emitting chip disposed in the cavity; a first light-pervious element disposed in the cavity; a dam structure disposed on the first light-pervious element, and having an inner dam, an outer dam, a first containing space formed in the inner dam, and a second containing space formed between the inner dam and outer dam; a first light-pervious packaging material filled in the first containing space; and a second light-pervious element combined with the dam structure.

The present invention further provides a method of fabricating an LED package structure, the method comprising: providing a package unit, the package unit having a submount with a cavity, and a light emitting chip disposed in the cavity; disposing a first light-pervious element in the cavity; disposing a dam structure on the first light-pervious element, the dam structure having an inner dam, an outer dam, a first containing space formed in the inner dam, and a second containing space formed between the inner dam and the outer dam; filling in the first containing space with a first light-pervious packaging material, the first light-pervious packaging material being larger in volume than the first containing space; and combining a second light-pervious element with the dam structure, thereby squeezing a portion of the first light-pervious packaging material into the second containing space.

In an embodiment of the present invention, wherein the inner dam of the dam structure is disposed on the first light-pervious element, and the outer dam is disposed on a rim of the cavity.

In an embodiment of the present invention, the package unit further comprises: leads disposed in the cavity and extending to a region outside of the submount; conductive elements electrically connected to the light emitting chip and the leads; and a second light-pervious packaging material filled in the cavity to encapsulate the leads, the light emitting chip, and the conductive elements.

In another embodiment of the present invention, the package unit further comprises: conductive pillars disposed in the cavity; conductive elements connected to the light emitting chip and the conductive pillars; and a second light-pervious packaging material filled in the cavity and encapsulating the conductive pillars, the light emitting chip, and the conductive elements.

In yet another embodiment of the present invention, the dam structure is formed by means of printing, dispensing, or covering a dry film and patterning the thy film. In an embodiment of the present invention, the inner dam and the outer dam are concentrically disposed on the first light-pervious element or on a rim of the cavity; the first transmission element is made of a silicon material; the dam structure is made of dry film, UV glue, B-stage epoxy resin, or glass frit; the second light-pervious element is made of silicon material; the second light-pervious element comprises a lens disposed thereon, or a lens contour; and the first light-pervious packaging material and second light-pervious packaging material are separately made of silica gel or epoxy resin, and the first light-pervious packaging material or the second light-pervious packaging material further comprise a fluorescent material.

In view of the above, in the LED package structure of the present invention and the method of fabricating the same, the first light-pervious element is first disposed in the cavity of the package unit, and then the multi-layered dam structure is concentrically disposed on the first light-pervious element and/or a rim of the cavity; subsequently, an excess amount of the first light-pervious packaging material is filled in the first containing space of the dam structure, and then surplus of the first light-pervious packaging material is squeezed into the second containing space of the dam structure while the second light-pervious element combines with the dam structure, thereby filling up the first containing space with the first light-pervious packaging material for eliminating gap, and further avoiding uneven thickness of the first light-pervious packaging material due to gap as in the prior technique, consequently maintaining high illumination efficiency, also enabling the second light-pervious element to tightly integrate with the dam structure and providing enhanced airtightness.

### BRIEF DESCRIPTION OF DRAWINGS

The invention can be more fully understood by reading the following detailed description of the preferred embodiments, with reference made to the accompanying drawings, wherein:

FIG. 1 is a sectional view diagram showing an LED of US Patent Application Publication Number 2010/0163898;

FIGS. 2A through 2E are sectional view diagrams depicting an LED package structure and a method of fabricating the same of a first embodiment according to the present invention, wherein FIG. 2A′ is another embodiment of 2A, FIG. 2E′ is another embodiment of FIG. 2E, and FIG. 2E″ shows a second light transmitting element with a lens contour;

FIGS. 3A through 3C are sectional view diagrams of an LED package structure and a method of fabricating the same of a second embodiment according to the present invention, wherein FIG. 3C′ is another embodiment of 3C; and

FIGS. 4A through 4C′ are sectional view diagrams depicting an LED package structure and a method of fabricating the same of a third embodiment according to the present invention, wherein FIG. 4C′ is another embodiment of FIG. 4C.

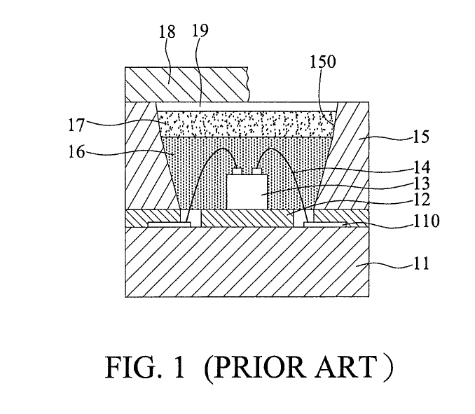

### DETAILED DESCRIPTION OF PREFERRED EMBODIMENTS

The following illustrative embodiments are provided to illustrate the disclosure of the present invention; those in the art can apparently understand these and other advantages and effects after reading the disclosure of this specification. The present invention can also be performed or applied by other different embodiments. The details of the specification may be on the basis of different points and applications, and numerous modifications and variations can be devised without departing from the spirit of the present invention.

### First Embodiment

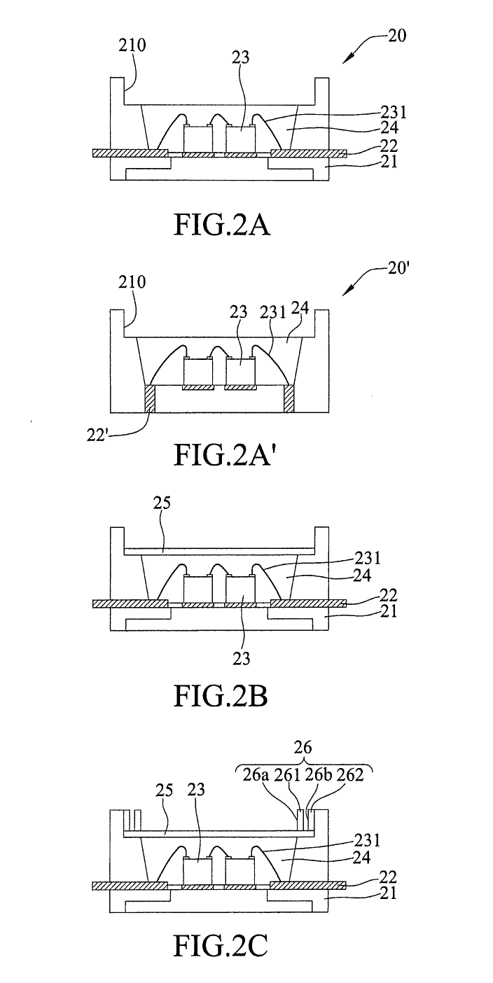

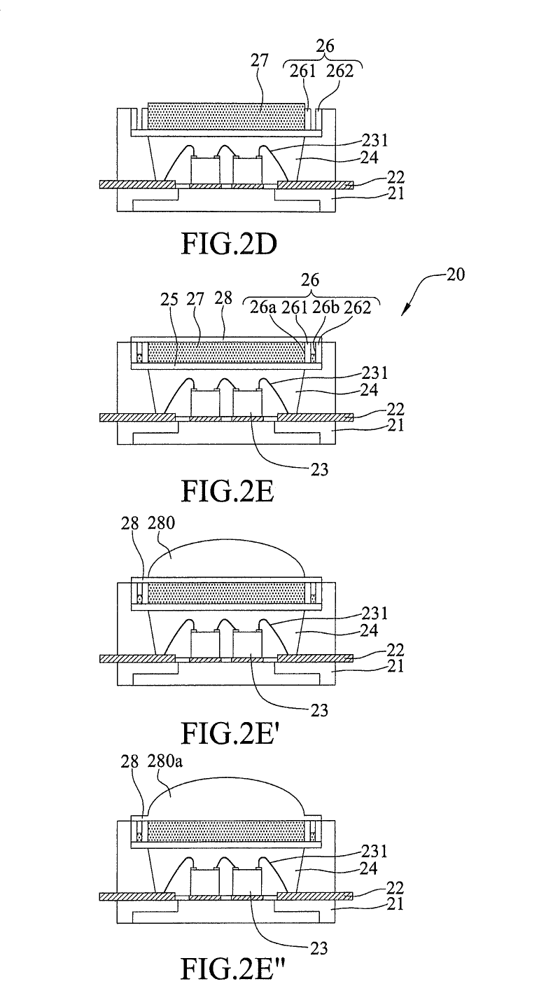

Please refer to FIGS. 2A through 2E″, which illustrate a method of fabricating an LED package structure of the first embodiment according to the present invention.

As shown in FIGS. 2A and 2A′, first, a package unit 20 is provided that comprises a submount 21 with a cavity 210, leads 22 disposed in the cavity 210 and extending to a region outside of the submount 21, a light emitting chip (or light emitting chips) 23 mounted on a bottom of the cavity 210, conductive elements 231 that are electrically connected to the light emitting chip 23 and the leads 22, and a second light-pervious packaging material 24 that is filled in the cavity 210 to encapsulate the leads 22, the light emitting chip 23, and the conductive elements 231. In an embodiment of the present invention, the conductive elements 231 are bonding wires, and the light emitting chips 23 may also be electrically connected to the leads 22 by means of flip chip via bumps. Alternatively, as the package unit 20′ shown in FIG. 2A′, the leads 22 may be replaced with conductive pillars 22′ disposed in the cavity 210, wherein the second light-pervious packaging material 24 also encapsulates the conductive pillars 22′, the light emitting chip 23, and the conductive elements 231. The package unit 20 shown FIG. 2A is described as follows.

As shown in FIG. 2B, a first light-pervious element 25 of a silicon material is embedded in the cavity 210, and the silicon material may be glass.

As shown in FIG. 2C, a dam structure 26 is formed around a rim of the first light-pervious element 25 by means of printing, and the dam structure 26 comprises an inner dam 261, an outer dam 262 concentrically disposed with the inner dam 261, a first containing space 26a formed in the inner dam 261, and a second containing space 26b formed between the inner dam 261 and the outer dam 262. In an embodiment of the present invention, the first containing space 26a has a flat area larger than or equal to a light illumination area of the light emitting chips 23, and the dam structure 26 is made of UV glue, B-stage epoxy resin, or glass fit. In addition to the printing means, the dam structure 26 may be formed by means of dispensing or covering a dry film and patterning the dry film.

As shown in FIG. 2D, the first containing space 26a is filled up with a first light-pervious packaging material 27. In an embodiment of the present invention, the first light-pervious packaging material 27 is larger in volume than the first containing space 26a. Hence, the first light-pervious packaging material 27 is taller than a top rim of the dam structure 26 due to substance surface tension.

Please refer to FIGS. 2E and 2E′, a second light-pervious element 28 made of, e.g., silicon material (can be glass) is combined with the dam structure 26, and a portion of the first light-pervious packaging material 27 is squeezed into the second containing space 26b, thereby enabling the first light-pervious packaging material 27 to fill up the first containing space 26a and avoiding uneven thickness of the first light-pervious packaging material 27, as shown in FIG. 2E. As shown in FIG. 2E′, a lens contour 280a is further included on a surface of the second light-pervious element 28 that opposes to another surface of the second light-pervious element 28 that is in contact with the first light-pervious packaging material 27.

In an embodiment of the present invention, the first light-pervious packaging material 27 and the second light-pervious packaging material 24 are made of silica gel or epoxy resin, the first light-pervious packaging material 27 or the second light-pervious packaging material 24 may further comprise a fluorescent material.

### Second Embodiment

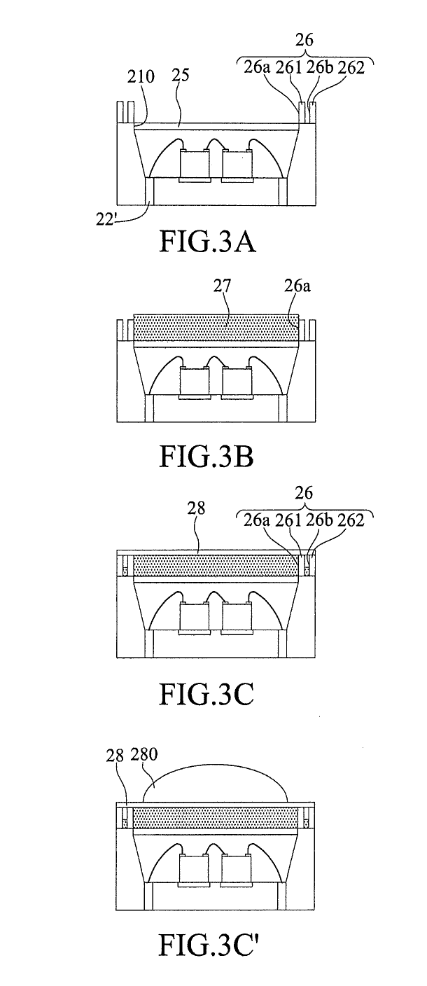

Please refer to FIGS. 3A through 3C, which illustrate a method of fabricating an LED package structure of the second embodiment according to the present invention. The second embodiment differs from the first embodiment in the means of fabricating the dam structure.

As shown in FIG. 3A, a structure the same as that shown in FIG. 2A′ is provided. Then, a first light-pervious element 25 is provided to seal the cavity 210, and a dam structure 26 is disposed around a rim of the cavity 210.

As shown in FIG. 3B, a first containing space 26a is filled with a first light-pervious packaging material 27, and the first light-pervious packaging material 27 is larger in volume than the first containing space 26a.

Please refer to FIGS. 3C and 3C′. A second light-pervious element 28 is combined with the dam structure 26, and the surplus of the first light-pervious packaging material 27 is squeezed into the second containing space 26b, as shown in FIG. 3C. The second light-pervious element 28 may further comprise a lens 280, as shown in FIG. 3C′. Similarly, the second light-pervious element 28 may further comprise a lens contour (not shown) on a surface opposing to another surface that is in contact with the first light-pervious packaging material 27.

### Third Embodiment

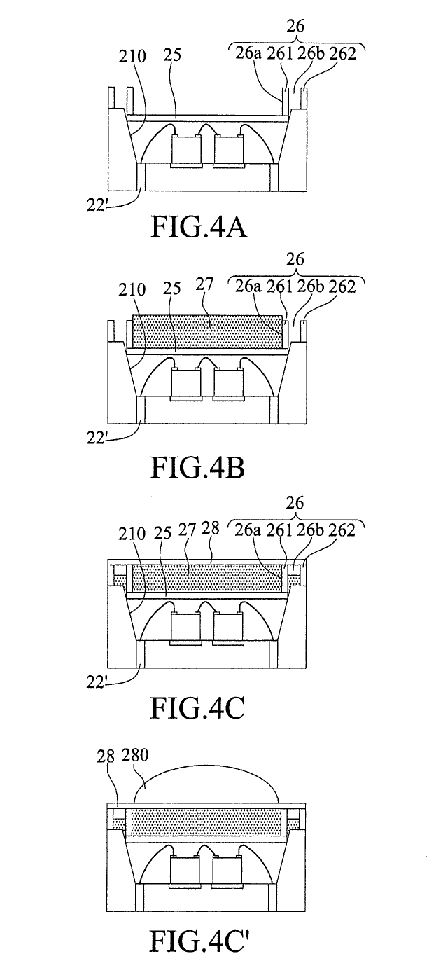

Please refer to FIGS. 4A through 4C′, which illustrate a method of fabricating an LED package structure of the third embodiment according to the present invention. The third embodiment differs from the first and second embodiment in the means of fabricating the dam structure.

As shown in FIG. 4A, a structure the same as that shown in FIG. 2A′ is provided. Then, a first light-pervious element 25 is provided to seal the cavity 210. Subsequently, an inner dam 261 is disposed on the first light-pervious element 25, and the outer dam 262 is disposed on a rim of the cavity 210. In an embodiment of the present invention, a first containing space 26a is formed in the inner dam 261, and a second containing space 26b is formed between the inner dam 261 and the outer dam 262.

As shown in FIG. 4B, the first containing space 26a is filled with a first light-pervious packaging material 27, and the first light-pervious packaging material 27 is larger in volume than the first containing space 26a.

As shown in FIGS. 4C and 4C′, a second light-pervious element 28 is combined with the dam structure 26, and the surplus of the first light-pervious packaging material 27 is squeezed into the second containing space 26b, as shown in FIG. 4C. A lens 280 may be further disposed on the second light-pervious element 28, as shown in FIG. 4C′. Similarly, the second light-pervious element 28 may further comprise a lens contour (not shown) on another surface opposing to the surface that is in contact with the first light-pervious packaging material 27.

According to the method, the present invention further provide an LED package structure, comprising: a package unit 20, 20′, a first light-pervious element 25, a dam structure 26, a first light-pervious packaging material 27, and a second light-pervious element 28.

The package unit 20 comprises a submount 21 with a cavity 210, leads 22 disposed in the cavity 210 and extending to a region outside of the submount 21, a light emitting chip (or light emitting chips) 23 mounted in the cavity 210, conductive elements 231 electrically connected to the light emitting chips 23 and the leads 22, and a second light-pervious material 24 filled in the cavity 210. In an embodiment of the present invention, the leads 22 functioning as an electrical connecting path may be replaced with conductive pillars 22′ disposed in the cavity 210, wherein the second light-pervious packaging material also encapsulates the leads 22 (or conductive pillars 22′), the light emitting chip 23, and the conductive elements 231.

The first light-pervious element 25 is made of a silicon material and disposed to seal the cavity 210.

The dam structure 26, which comprises an inner dam 261 and an outer dam 262, is disposed concentrically on the first light-pervious element 25 or on a rim of the cavity 210. In an embodiment of the present invention, the inner dam 261 is disposed on the first light-pervious element 25, while the outer dam 262 is disposed on a rim of the cavity 210. A first containing space 26a may be disposed in the inner dam 261, and a second containing space 26b may be formed between the inner dam 261 and the outer dam 262. The dam structure 26 may be made of dry film, UV glue, B-stage epoxy resin, or glass frit.

The first containing space 26a is completely filled by the first light-pervious packaging material 27, and the second containing space 26b is filled with a portion of the first light-pervious packaging material 27.

The second light-pervious element 28 is made of silicon material, and combines with the dam structure 26. The LED package structure may further comprise a lens 280 disposed on the second light-pervious element 28.

In view of the above, according to the LED package structure and the method of fabricating the same according to the present invention, the first light-pervious element is disposed to seal the cavity of the package unit; the dam structure comprising the inner dam and the outer dam is concentrically disposed on the first light-pervious element and/or a rim of the cavity; and the first containing space of the dam structure is filled with excess amount of first light-pervious packaging material, thereby allowing the surplus of the first light-pervious packaging material to be squeezed into the second containing space of the dam structure while combining the second light-pervious element with the dam structure. Consequently, the first containing space is filled with the first light-pervious packaging material without leaving a gap, thereby avoiding the problem of uneven thickness of the first light-pervious packaging material caused by existing gap as happened in prior technique, consequently maintaining high illumination efficiency.

Furthermore, the multi-layered dam structure having the inner dam and the outer dam, providing a better means for tightly integrating the second light-pervious element with the dam structure.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. An LED package structure, comprising:
a package unit having a submount with a cavity, and a light emitting chip disposed in the cavity;
a first light-pervious element disposed in the cavity;
a dam structure disposed on the first light-pervious element, and having an inner dam, an outer dam, a first containing space formed in the inner dam, and a second containing space formed between the inner dam and outer dam;
a first light-pervious packaging material filled in the first containing space; and
a second light-pervious element combined with the dam structure.

2. The LED package structure of claim 1, wherein the package unit further comprises:
leads disposed in the cavity and extending to a region outside of the submount;
conductive elements electrically connected to the light emitting chip and the leads; and
a second light-pervious packaging material filled in the cavity and encapsulating the leads, the light emitting chip, and the conductive elements.

3. The LED package structure of claim 2, wherein the second light-pervious packaging material is silica gel or epoxy resin.

4. The LED package structure of claim 3, wherein the second light-pervious packaging material further comprises a fluorescent material.

5. The LED package structure of claim 1, wherein the package unit further comprises:
conductive pillars disposed in the cavity;
conductive elements electrically connected the light emitting chip and the conductive pillars; and
a second light-pervious packaging material filled in the cavity and encapsulating the conductive pillars, the light emitting chip, and the conductive elements.

6. The LED package structure of claim 5, wherein the second light-pervious packaging material is silica gel or epoxy resin.

7. The LED package structure of claim 6, wherein the second light-pervious packaging material further comprises a fluorescent material.

8. The LED package structure of claim 1, wherein the first light-pervious packaging material is silica gel or epoxy resin.

9. The LED package structure of claim 8, wherein the first light-pervious packaging material further comprises a fluorescent material.

10. The LED package structure of claim 1, wherein the inner dam and the outer dam are concentrically disposed on the first light-pervious element.

11. The LED package structure of claim 1, wherein the first containing space is completely filled with the first light-pervious packaging material, and the second containing space is filled with a portion of the first light-pervious packaging material.

12. The LED package structure of claim 1, wherein the first light-pervious element is made of a silicon material.

13-14. (canceled)

15. An LED package structure, comprising:
a package unit having a submount with a cavity, and a light emitting chip disposed in the cavity;
a first light-pervious element disposed in the cavity;
a dam structure disposed on a rim of the cavity and having an inner dam, an outer dam, a first containing space formed in the inner dam, and a second containing space formed between the inner dam and the outer dam;
a first light-pervious packaging material filled in the first containing space; and
a second light-pervious element combined with the dam structure.

16. The LED package structure of claim 15, wherein the package unit further comprises:
leads disposed in the cavity and extending to a region outside of the submount;
conductive elements electrically connected to the light emitting chip and the leads; and
a second light-pervious packaging material filled in the cavity and encapsulating the leads, the light emitting chip, and the conductive elements.

17-18. (canceled)

19. The LED package structure of claim 15, wherein the package unit further comprises:
conductive pillars disposed in the cavity;
conductive elements electrically connected to the light emitting chip and the conductive pillars; and
a second light-pervious packaging material filled in the cavity and encapsulating the conductive pillars, the light emitting chip, and the conductive elements.

20. The LED package structure of claim 19, wherein the second light-pervious packaging material is silica gel or epoxy resin.

21-28. (canceled)

29. An LED package structure, comprising:
a package unit having a submount with a cavity, and a light emitting chip disposed in the cavity;
a first light-pervious element disposed in the cavity;
a dam structure having an inner dam disposed on the first light-pervious element, an outer dam disposed on a rim of the cavity, a first containing space formed in the inner dam, and a second containing space formed between the inner dam and the outer dam;
a first light-pervious packaging material filled in the first containing space; and
a second light-pervious element combined with the dam structure.

30. The LED package structure of claim 29, wherein the package unit further comprises:
leads disposed in the cavity and extending to a region outside of the submount;
conductive elements electrically connected to the light emitting chip and the leads; and
a second light-pervious packaging material filled in the cavity and encapsulating the leads, the light emitting chip, and the conductive elements.

31-32. (canceled)

33. The LED package structure of claim 29, wherein the package unit further comprises:
conductive pillars disposed in the cavity;
conductive elements electrically connected to the light emitting chip and the conductive pillars; and
a second light-pervious packaging material filled in the cavity and encapsulating the conductive pillars, the light emitting chip, and the conductive elements.

34-42. (canceled)

43. A method of fabricating an LED package structure, comprising:
providing a package unit, the package unit having a submount with a cavity, and a light emitting chip disposed in the cavity;
disposing a first light-pervious element in the cavity;
disposing a dam structure on the first light-pervious element, the dam structure having an inner dam, an outer dam, a first containing space formed in the inner dam, and a second containing space formed between the inner dam and the outer dam;
filling in the first containing space with a first light-pervious packaging material, the first light-pervious packaging material being larger in volume than the first containing space; and
combining a second light-pervious element with the dam structure, thereby squeezing a portion of the first light-pervious packaging material into the second containing space.

44-47. (canceled)

48. A method of fabricating an LED package structure, comprising:
providing a package unit, the package unit having a submount with a cavity, and a light emitting chip disposed in the cavity;
disposing a first light-pervious element in the cavity;
disposing on a rim of the cavity a dam structure having an inner dam, an outer dam, a first containing space formed in the inner dam, and a second containing space formed between the inner dam and the outer dam;
filling in the first containing space with a first light-pervious packaging material that is larger in volume than the first containing space; and
combining a second light-pervious element to the dam structure, thereby squeezing a portion of the first light-pervious packaging material into the second containing space.

49. The method of claim 48, wherein the package unit further comprises:
leads disposed in the cavity and extending to a region outside of the submount;
conductive elements electrically connected to the light emitting chip and the leads; and
a second light-pervious packaging material filled in the cavity and encapsulating the leads, the light emitting chip, and the conductive elements.

50. The method of claim 48, wherein the package unit further comprises:
conductive pillars disposed in the cavity;
conductive elements electrically connected to the light emitting chip and the conductive pillars; and
a second light-pervious packaging material filled in the cavity and encapsulating the conductive pillars, the light emitting chip, and the conductive elements.

51-52. (canceled)

53. A method of fabricating an LED package structure, comprising:
providing a package unit, the package unit having a submount with a cavity, and a light emitting chip disposed in the cavity;
disposing a first light-pervious element in the cavity;
disposing a dam structure having an inner dam disposed on the first light-pervious element, an outer dam disposed on a rim of the cavity, a first containing space formed in the inner dam, and a second containing space formed between the inner dam and the outer dam;
filling in the first containing space with a first light-pervious packaging material that is larger in volume than the first containing space; and
combining a second light-pervious element to the dam structure, thereby squeezing a portion of the first light-pervious packaging material into the second containing space.

54. The method of claim 53, wherein the package unit further comprises:
leads disposed in the cavity and extending to a region outside of the submount;
conductive elements electrically connected to the light emitting chip and the leads; and
a second light-pervious packaging material filled in the cavity and encapsulating the leads, the light emitting chip, and the conductive elements.

55. The method of claim 53, wherein the package unit further comprises:
conductive pillars disposed in the cavity;
conductive elements electrically connected to the light emitting chip and the conductive pillars; and
a second light-pervious packaging material filled in the cavity and encapsulating the conductive pillars, the light emitting chip, and the conductive elements.

56-57. (canceled)
